(19) United States
(12) Patent Application Publication
(10) Pub. No.: US 2002/0052079 A1
(43) Pub. Date: May 2, 2002

(54) Memory cell structure of flash memory having circumventing floating gate and method for fabricating the same

(76) Inventor: Wen Ying Wen, Hsinchu Hsien (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 09/948,675

(22) Filed: Sep. 10, 2001

Related U.S. Application Data
(63) Continuation-in-part of application No. 09/653,319, filed on Sep. 1, 2000.

(51) Int. Cl. H01L 21/336

(52) U.S. Cl. 438/257

(57) ABSTRACT

The present invention relates to a memory cell structure of a flash memory and a method for fabricating the same and, more particularly, to a flash memory having circumventing floating gates and a method for fabricating the same. In the proposed memory cell, a floating gate and a tunneling oxide are etched to form an annular shape situated between a drain, a source, and two field oxides. An interpoly dielectric and a control gate cover in turn on the floating gate and on the surface of the substrate not covered by the floating gate by means of self-alignment. The present invention can not only achieve self-alignment to form the control gate and apply to high-integration memory cells with small areas, but also can effectively increase the high capacitance coupling ratio thereof to enhance the tunneling effect of hot electrons.

### FIELD OF THE INVENTION

The present invention relates to a memory cell structure of a flash memory and a method for fabricating the same and, more particularly, to a flash memory having circumventing floating gates and a method for fabricating the same. The present invention can not only achieve self-alignment to form control gates and apply to high-integration memory cells with small areas, but also can effectively increase the high capacitance coupling ratio thereof to enhance the tunneling effect of hot electrons.

### BACKGROUND OF THE INVENTION

Flash memories have been widely used in electronic products such as portable computers or communication apparatuses because of their non-volatile functions of electrically writing and erasing. Flash memories can generally be categorized into two types according to the shape of their gates: the stacked gate type and the split gate type.

FIG. 1 shows a cross-sectional view of a memory cell of a flash memory of stacked gate type in prior art. As shown in the figure, a stacked gate is formed on a semiconductor substrate 11. The stacked gate comprises from bottom to top a gate oxide 13, a floating gate 15, an interpoly dielectric 17, and a control gate 19. A drain region 12 and a source region 14 are formed in the substrate 11 respectively at one side of the stacked gate by ion implantation. Through applied voltage between the control gate 19 and the drain 12 and the source 14, a channel and hot electrons can be formed under the floating gate 15 in the substrate 11. These hot electrons are injected from the drain 12 through the gate oxide 13 into the floating gate 15 by means of hot electron injection so as to complete a program process of writing data. Contrarily, electrons are released from the floating gate 15 to the source 14 by means of the Fowler-Nordheim (FN) tunneling effect for erasing data.

However, for a flash memory of stacked gate type, it is difficult to control the number of electrons released from the floating gate 15 during the data-erasing procedure. Over erase may easily arise, deteriorating the quality and reliability of the flash memory.

Therefore, flash memories of split gate type have been developed. As shown in FIG. 2, a thin oxide 23, a floating gate 25, a dielectric film 271, and a control gate 29 are successively deposited on a semiconductor substrate 21. Next, a source region 22 and a drain region 24 are formed at proper positions in the substrate 21 by ion implantation. One end of the control gate 29 has a selecting gate part 295 extending to the drain 24. A selecting gate oxide 275 is disposed between the selecting gate part 295 of the control gate 29 and the drain 24.

Flash memories of split gate type can effectively solve the problem of over erase occurring easily in flash memories of stacked gate type. However, the length of the selecting gate part 295 has a certain limit. Leakage current will be generated if its length is reduced. Moreover, it is difficult to align the relative positions of the source 22, the drain 24, the control gate 29, and the floating gate. The lengths of the selecting gate part 295 and the floating gate 25 thus can not be effectively reduced. Additionally, to enhance the efficiencies of writing and erasing data, larger memory cell size is needed to achieve high capacitance coupling ratio. Therefore, the area of memory cell thereof will be large so that integration density of memory cell can not be effectively increased.

### SUMMARY AND OBJECTS OF THE PRESENT INVENTION

The primary object of the present invention is to provide a flash memory structure and a method for fabrication the same. In the proposed flash memory, an annular floating gate situated between the drain and the source is exploited. An interpoly dielectric and a control gate are stacked on the surface of the floating gate and on the substrate exposed at the center of the floating gate through self-alignment. Thereby above mentioned problem can be overcome, and reliability of devices can be enhanced.

Another object of the present invention is to provide a flash memory structure and a method for fabricating the same. In the proposed flash memory, an interpoly dielectric and a floating gate circumvent the periphery of the bottom of the control gate to enhance its insulating effect, thus achieving efficient writing or erasing for a memory cell of the flash memory.

Yet another object of the present invention is to provide a flash memory structure and a method for fabricating the same. In the proposed flash memory, the interpoly dielectric circumventing the floating gate is an oxide/nitride/oxide (ONO) structure or an oxide/nitride (ON) structure. The quality and thickness of the interpoly dielectric can be exactly controlled. Flash memory cells of high capacitance coupling ratio and low leakage current can thus be produced.

Still yet another object of the present invention is to provide a flash memory structure and a method for fabricating the same. The proposed fabrication method is compatible to the general fabrication process of CMOS devices.

To accomplish above objects, the present invention proposes a memory cell structure of a flash memory. The proposed memory cell structure comprises mainly a semiconductor substrate, an annular floating gate, an interpoly dielectric, and a control gate. A source and a drain are formed in the substrate. Part region of the floating gate covers on the surfaces of the source and the drain. A tunneling oxide electrically insulates the source and the drain. The interpoly dielectric covers on the floating gate, the carved-out center of the floating gate, and the surface of the substrate exposed at the periphery of the floating gate. The control gate covers on the surface of the interpoly dielectric. The interpoly dielectric is an ONO structure or an ON structure.

The present invention also provides a method for fabricating a memory cell structure of a flash memory. The proposed fabrication method comprises the following steps: providing a semiconductor substrate; forming a pad oxide and a silicon nitride (SiN) on the surface of the substrate; etching out the patterns of the pad oxide and the SiN to reserve only parts thereof situated between two field oxides by the photolithography and etching techniques; forming in turn a tunneling oxide and a first poly-silicon; etching out the pattern of the first poly-silicon to expose the SiN and the tunneling oxide by the photolithography and anisotropic dry etching techniques to form an annular floating gate circumventing the SiN and the pad oxide; removing the SiN and the pad oxide; forming in turn an ON or an ONO with thickness larger than that of the tunneling oxide on the floating gate and the exposed surface of the substrate; forming a second poly-silicon on the surface of the ON or ONO; etching out the patterns of the second poly-silicon and the ON or ONO to form a control gate; forming a source and a drain in the exposed substrate by ion implantation; and forming metal layers or metal contact windows by means of conventional techniques.

The various objects and advantages of the present invention will be more readily understood from the following detailed description when read in conjunction with the appended drawings, in which:

### BRIEF DESCRIPTION OF DRAWING

FIG. 1 is a cross-sectional view of a memory cell of a flash memory of stacked gate type in prior art;

FIG. 2 is a cross-sectional view of a memory cell of a flash memory of split gate type in prior art;

FIGS. 3A to 3G show the fabrication flowchart of a memory cell of a flash memory according to a preferred embodiment of the present invention;

FIGS. 4A to 4C are diagrams of the array structure of a flash memory in part of the fabrication procedures shown in FIG. 3;

FIG. 5 is a cross-sectional view of a memory cell of a flash memory of according to a preferred embodiment of the present invention.

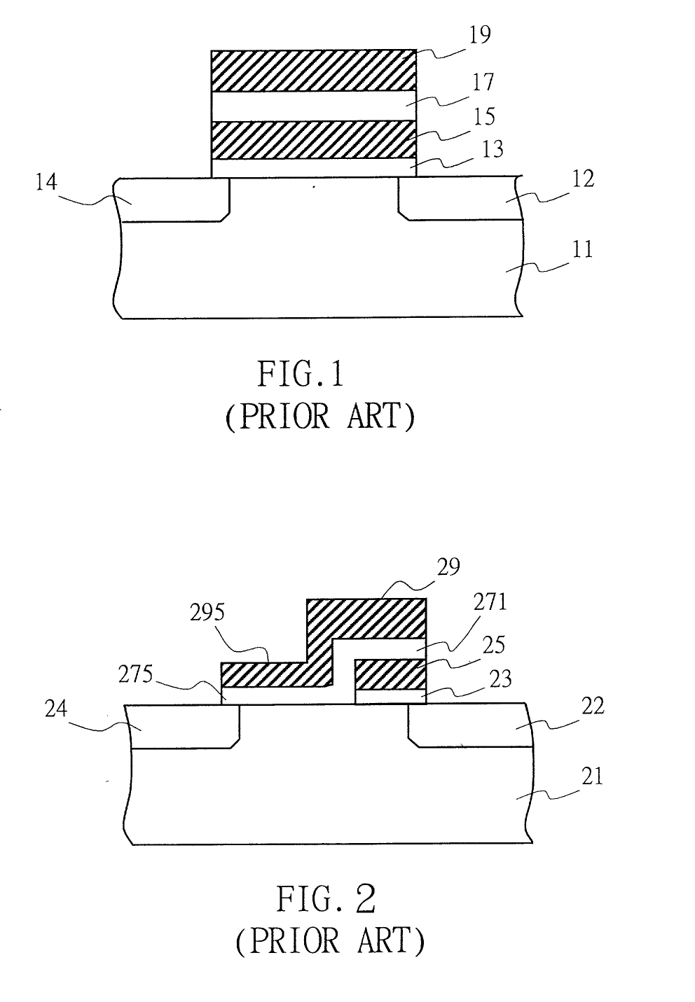

### DETAILED DESCRIPTION OF PREFERRED EMBODIMENT

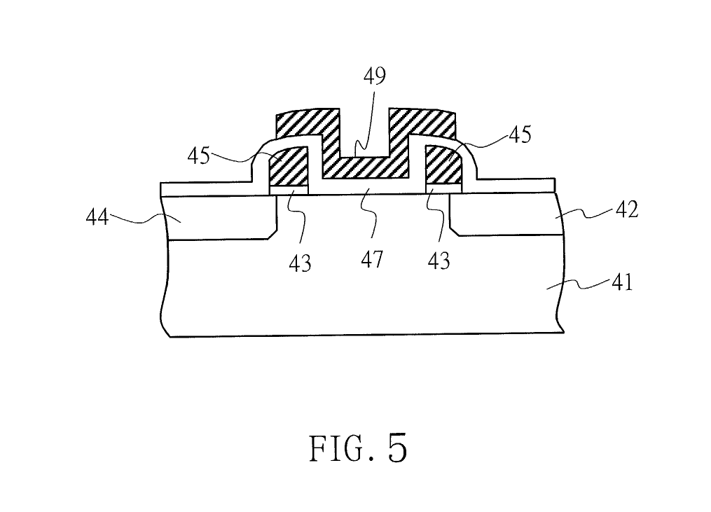

As shown in FIG. 5, the memory cell structure of a flash memory according to a preferred embodiment of the present invention comprising: a semiconductor substrate 41 having a source 42 and a drain 44 therein. An annular floating gate 45 has part region thereof covering on the surfaces of said source 42 and said drain 44, and a tunneling oxide 43 electrically insulates the source 42 and the drain 44. Said substrate 41 being exposed in the carved-out center of said floating gate 45. An interpoly dielectric 47 covering on the surface of said floating gate 45, on the center of said floating gate 45, and on the surface of said substrate 41 exposed at the periphery of said floating gate 45, and a control gate 49 covers on the surface of said interpoly dielectric 47.

Additionally, the floating gate is an annular shape formed by poly-silicon spacers, and the interpoly dielectric 47 is an oxide-nitride-oxide (ONO) structure or an oxide-nitride (ON) structure of good dielectric characteristic. Said interpoly dielectric 47 and said control gate 49 circumvent the center and the periphery of said floating gate, and the thickness of said interpoly dielectric 47 is larger than that of said tunneling oxide 43.

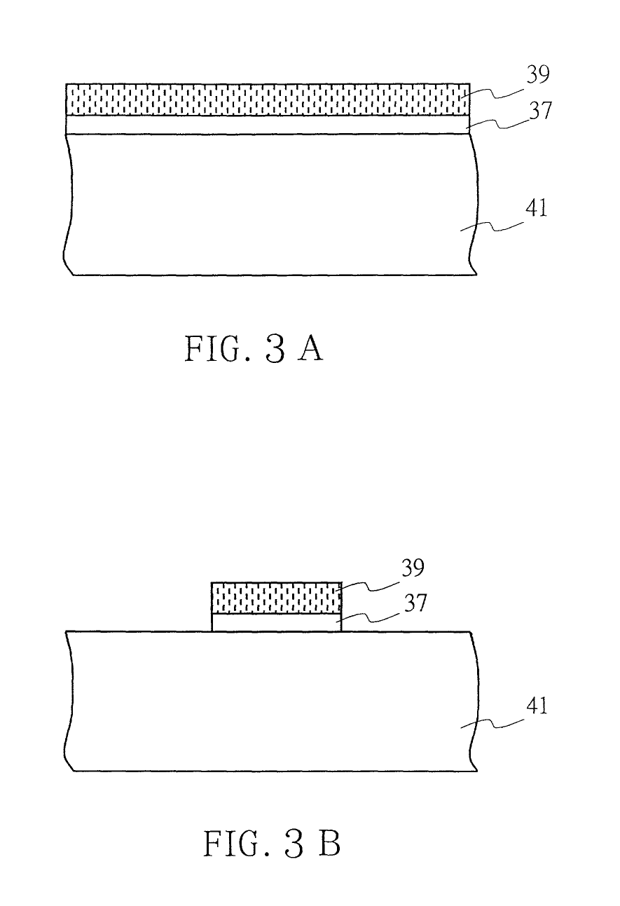

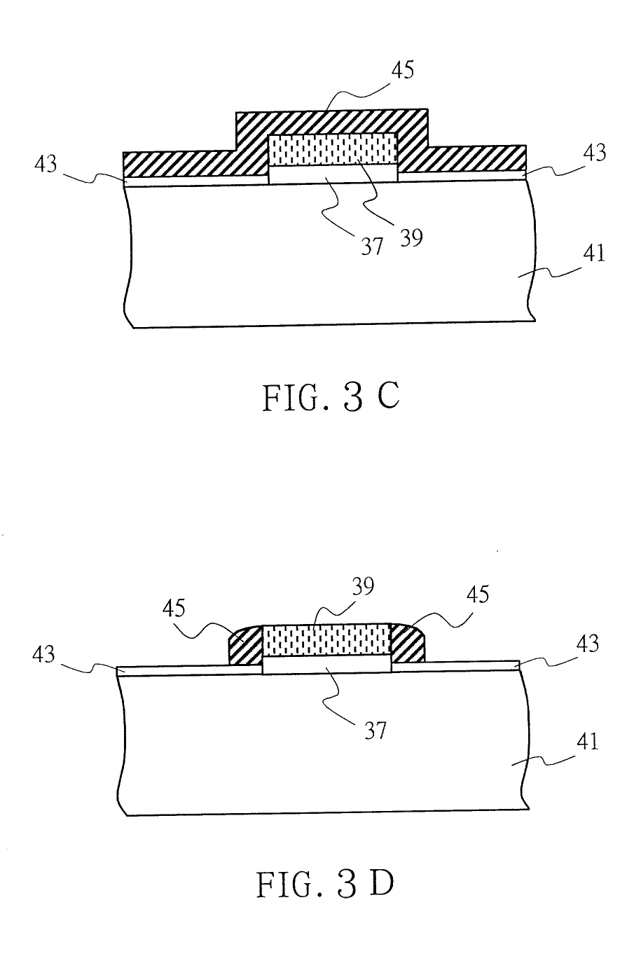

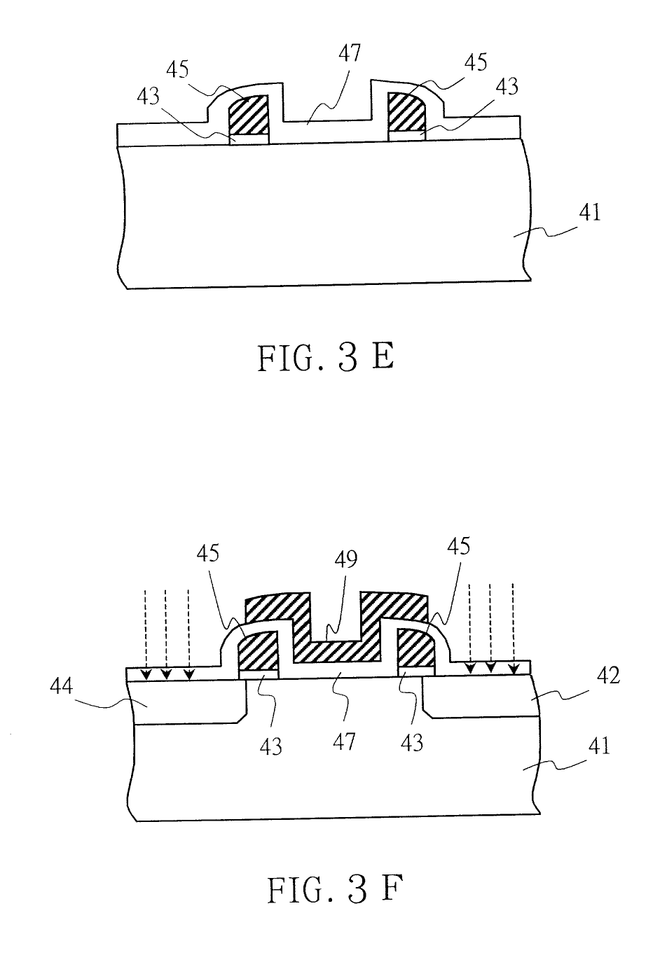

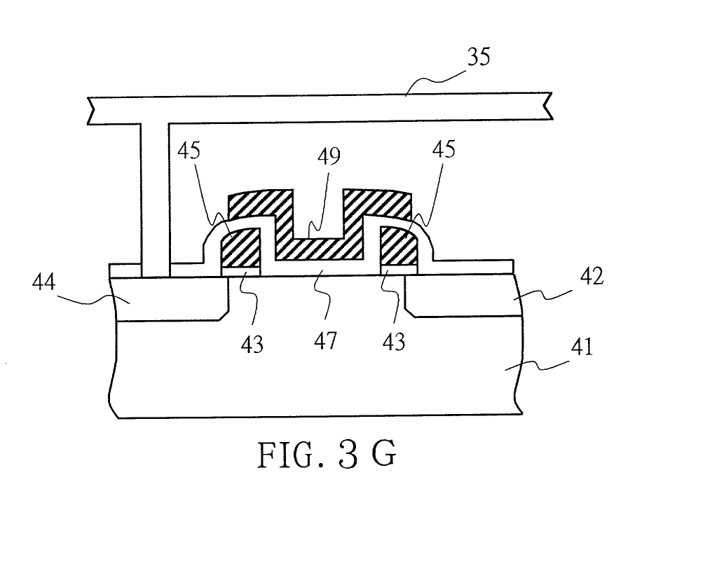

As shown in FIGS. 3A to 3G, the fabrication method of a memory cell according to a preferred embodiment of the present invention comprising the steps of:

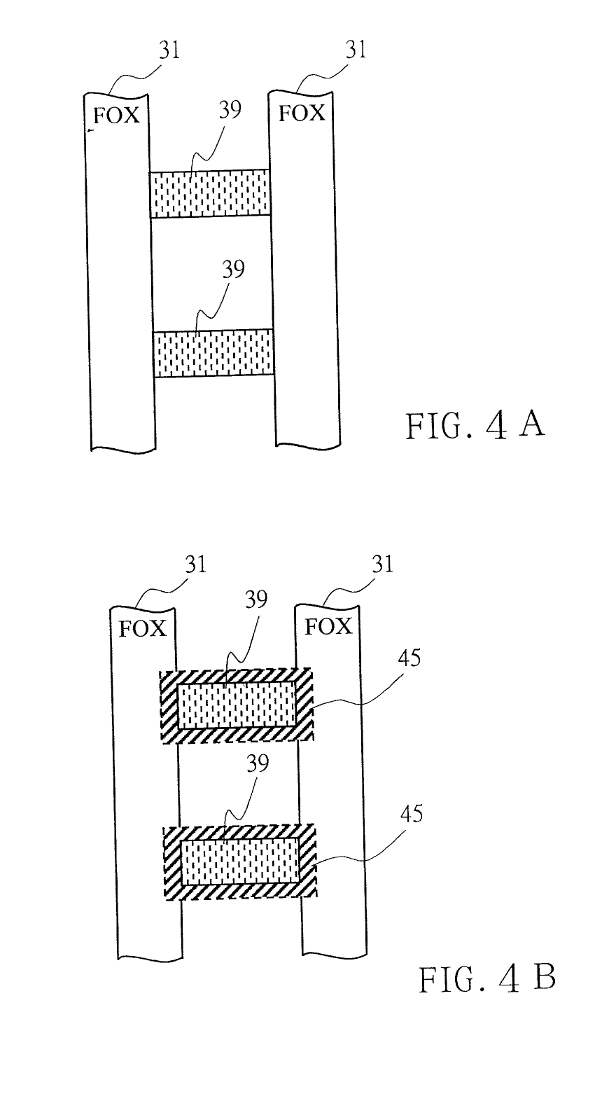

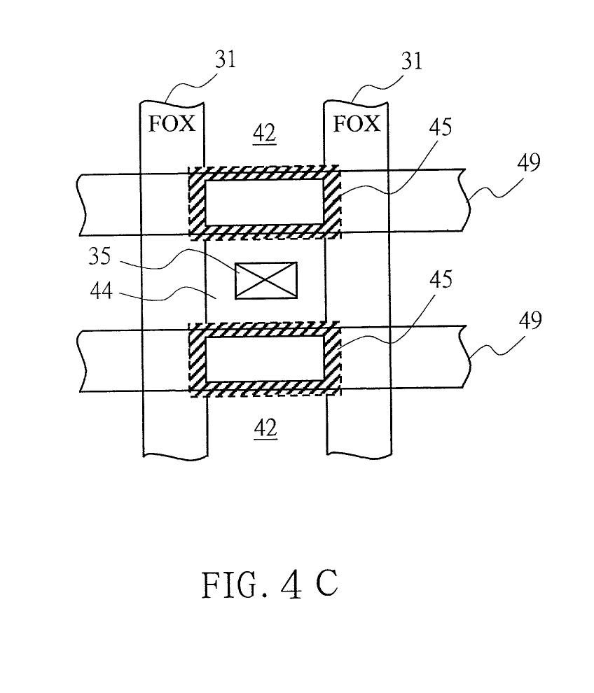

Step A (as shown in FIGS. 3A and 4A): providing a semiconductor substrate 41; forming a pad oxide 37 and a SiN 39 on the surface of the substrate 41; forming a plurality of field oxides 31 in specific regions of the substrate 41 by the techniques of photolithography, etching, and oxidation; defining the action area of the memory cell between the two field oxides 31,

Step B (as shown in FIGS. 3B and 4A): etching out the patterns of the pad oxide 37 and the SiN 39 to reserve only parts thereof situated between the two field oxides 31 by the photolithography and etching techniques,

Step C (as shown in FIG. 3C): forming in turn a tunneling oxide 43 and a first poly-silicon 45 (The poly-silicon 45 will cover on the surface of the SiN 39 because the tunneling oxide 43 can not be attached on the surface of the SiN 39.),

Step D (as shown in FIGS. 3D and 4B): etching the first poly-silicon 45 to expose the SiN 39 or the tunneling oxide 43 to form poly-silicon spacers by the anisotropic dry etching technique so that an annular floating gate 45 circumventing the SiN 39 and the pad oxide 37 is formed,

Step E (as shown in FIG. 3E): removing the SiN 39 or even the pad oxide 37 and the tunneling oxide 43 not covered by the floating gate 45; forming in turn an interpoly dielectric 47 such as an ON or an ONO with thickness larger than that of the tunneling oxide 43 on the floating gate 45 and the exposed surface of the substrate 41 (If the pad oxide 37 and the tunneling oxide 43 are not removed, they will also be compatible with the first oxide of the ONO or ON 47.),

Step F (as shown in FIGS. 3F): forming a second poly-silicon 49 on the surface of the ON or ONO 47; etching out the pattern of the second poly-silicon 49 to form a control gate 49 by the photolithography and etching techniques; forming a source 42 and a drain 44 in the exposed substrate 41 by ion implantation, and

Step G (as shown in FIGS. 3G and 4C): forming a metal contact window 35 or a metal layer by means of conventional techniques.

As can be seen in the above step E and step F, the interpoly dielectric 47 is an ONO or an ON of good dielectric characteristic. Better dielectric characteristic and thickness control thus can be achieved. Additionally, because the floating gate 45, the interpoly dielectric 47, and the control gate 49 of the present invention are symmetric structures, there is no aligning problem, resulting in absolute self-alignment. Moreover, because the action areas of the control gate 49 and the floating gate 45 are larger than those in prior art, capacitance coupling ratio and tunneling effect of electrons thereof can be enhanced effectively. Therefore, a memory cell of a flash memory of efficient writing or erasing and with low leakage current can obtained.

Evidently, the source 42 and the drain 44 can be formed by ion implantation before step E. The ONO or ON 47 and the control gate 49 are then formed. Thereby the effects and objects of the above embodiment can also be achieved.

The operation conditions of a memory cell of a flash memory according to the present invention are listed in Table 1.

TABLE 1

| | Control gate | Source | Drain | Substrate |
|---|---|---|---|---|
| Program | Vₚₚ | Floating | 0 V | Ground |
| Erase | 0 V | Vₚₚ | Floating | Ground |
| Read | V_{cc} | 0 V | V_{cc} | Ground |

During the program process, the applied voltage on the control gate 49 is V_{CG}=Vₚₚ (high), while the applied voltage on the drain 44 is V_{D}=0 V. The source 42 is floating or a working voltage V_{CC} is applied thereon. The substrate 41 is grounded. Thereby the hot electrons generated in the channel near the drain 44 can be injected into the annular floating gate 45.

During the erase process, the applied voltage on the source 42 is V_{S}=Vₚₚ (high), while the applied voltage on the control gate 49 is V_{CG}=0 V. The drain 44 is floating or grounded. The substrate 41 is grounded. Or alternatively, the applied voltage on the drain 44 is V_{D}=Vₚₚ (high), while the applied voltage on the control gate 49 is V_{CG}=0 V. The source 42 is floating or grounded. The substrate 41 is similarly grounded. Thereby the electrons existing in the control gate 45 can move into the source 42 or the drain 44 through the FN tunneling effect.

In the preferred embodiment, the source 42 is selected as the passage for removing hot electrons in consideration of easier page erase. Contrarily, the drain 44 is selected as the passage for removing hot electrons because there are less lines connected to the drain 44 as compared to those connected to the source 42, resulting in less voltage interference. Therefore, different circuits of applied voltages can be selected according to different necessity.

During the read process, the voltages applied on the control gate 45 and the drain 44 are the same working voltages V_{cc} or V_{cc}/2. In other words, V_{CG}=V_{D}=Vₚₚ. The voltage applied on the source 42 is V_{S}=0 V. The substrate is grounded.

Summing up, the present invention relates to a memory cell structure of a flash memory and a method for fabricating the same and, more particularly, to a flash memory having circumventing floating gates and a method for fabricating the same. The present invention can not only achieve self-alignment to form the control gate and apply to high-integration memory cells with small areas, but also can effectively increase the high capacitance coupling ratio thereof to enhance the tunneling effect of hot electrons.

Although the present invention has been described with reference to the preferred embodiments thereof, it will be understood that the invention is not limited to the details thereof. Various substitutions and modifications have suggested in the foregoing description, and other will occur to those of ordinary skill in the art. Therefore, all such substitutions and modifications are intended to be embraced within the scope of the invention as defined in the appended claims.

I claim:

1. A memory cell structure of a flash memory, comprising mainly:
a semiconductor substrate having a source and a drain therein;
an annular floating gate with part region thereof covering on the surfaces of said source and said drain, said floating gate being electrically insulated from said source and said drain via a tunneling oxide, said substrate being exposed in the carved-out center of said floating gate;
an interpoly dielectric covering on the surface of said floating gate, on the center of said floating gate, and on the surface of said substrate exposed at the periphery of said floating gate; and
a control gate covering on the surface of said interpoly dielectric.

2. The memory cell structure of claim 1, wherein said interpoly dielectric is an oxide-nitride-oxide structure.

3. The memory cell structure of claim 1, wherein said interpoly dielectric is an oxide-nitride structure.

4. The memory cell structure of claim 1, wherein said interpoly dielectric and said control gate circumvent the center and the periphery of said floating gate.

5. The memory cell structure of claim 1, wherein the thickness of said interpoly dielectric is larger than that of said tunneling oxide.

6. The memory cell structure of claim 1, wherein said floating gate is an annular shape formed by poly-silicon spacers.
